(19) United States
(12) Patent Application Publication
(10) Pub. No.: US 2017/0187292 A1
(43) Pub. Date: Jun. 29, 2017

(54) System and Method for a Switching Circuit

(71) Applicant: Infineon Technologies Austria AG, Villach (AT)

(72) Inventors: Marcus Schaemann, Munich (DE); Tiam Poh Lau, Singapore (SG)

(21) Appl. No.: 14/981,444

(22) Filed: Dec. 28, 2015

(51) Int. Cl. H02M 3/335; G01R 23/02; G01R 25/00

(52) U.S. Cl. CPC H02M 3/33507; G01R 25/00; G01R 23/02; H02M 2001/0009

(57) ABSTRACT

According to an embodiment, a switched-mode power supply (SMPS) includes a controller including a measurement circuit and a pulse width modulator having an output configured to be coupled to a control node of a switch of the SMPS. The measurement circuit is configured to determine a phase angle of an AC line input of the SMPS and modulate a frequency of a control signal at the output of the pulse width modulator based on the phase angle.

### TECHNICAL FIELD

The present invention relates generally to electronic circuits, and, in particular embodiments, to a system and method for a switching circuit.

### BACKGROUND

Power supply systems are pervasive in many electronic applications including computers, automobiles, and consumer and industrial lighting, for example. Generally, voltages within a power supply system are generated by performing a DC-DC, DC-AC, and/or AC-DC conversion by operating a switch loaded with an inductor or transformer. One class of such systems includes switched-mode power supplies (SMPS). An SMPS is usually more efficient than other types of power conversion systems because power conversion is performed by controlled charging and discharging of the inductor or transformer and reduces energy lost due to power dissipation across resistive voltage drops.

An SMPS usually includes at least one switch and an inductor or transformer. Some specific topologies include buck converters, boost converters, and flyback converters, among others. A control circuit is commonly used to open and close the switch to charge and discharge the inductor or transformer. In some applications, the current supplied to the load and/or the voltage supplied to the load is controlled via a feedback loop.

For some power supply systems, switching is performed at a fixed frequency while the duty cycle is adjusted to control an output voltage, output current, or output power. For example, in some light emitting diode (LED) applications, an AC input voltage is converted to a DC output voltage in an SMPS to power a string of series connected LEDs. By adjusting the DC output to provide more or less current or voltage, the intensity of the light from the string of series connected LEDs may be adjusted according to a user's demand. The switching frequency of the SMPS may have various effects on the light emitted, the circuit noise produced, or the electromagnetic interference (EMI) produced.

### SUMMARY

According to an embodiment, a switched-mode power supply (SMPS) includes a controller including a measurement circuit and a pulse width modulator having an output configured to be coupled to a control node of a switch of the SMPS. The measurement circuit is configured to determine a phase angle of an AC line input of the SMPS and modulate a frequency of a control signal at the output of the pulse width modulator based on the phase angle.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a system block diagram of an embodiment switching power supply;

FIG. 2 illustrates a schematic diagram of an embodiment switching power supply;

FIG. 3 illustrates a functional block diagram of an embodiment controller for a switching power supply;

FIGS. 4A, 4B, 4C, 4D, 4E, and 4F illustrate waveform diagrams from an embodiment switching power supply;

FIGS. 5A and 5B illustrate waveform diagrams from another embodiment switching power supply;

FIGS. 6A and 6B illustrate waveform diagrams from a further embodiment switching power supply;

FIG. 7 illustrates a functional block diagram of another embodiment controller for a switching power supply;

FIG. 8 illustrates a schematic diagram of still another embodiment switching power supply; and

FIG. 9 illustrates a flowchart diagram of an embodiment method of operating a switching circuit.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

Description is made with respect to various embodiments in a specific context, namely switching circuits, such as SMPS, and more particularly, AC-DC switching power supplies. Some of the various embodiments described herein include LED lighting systems, AC-DC power supplies, frequency modulation of switching power supplies and converters, and controllers for switching power supplies. In other embodiments, aspects may also be applied to other applications involving any type of switching circuit according to any fashion as known in the art.

Switching power supplies that operate with a fixed switching frequency may exhibit some undesirable characteristics. For example, using a fixed switching frequency for switching power supplies may lead to flicker in some lighting applications supplied by the switching power supply. In some applications, using a fixed switching frequency for switching power supplies may lead to excessive electromagnetic interference (EMI). In additional applications, using a fixed switching frequency for switching power supplies may lead to excessive or undesirable levels of total harmonic distortion (THD) or energy per harmonic frequency. Thus, according to various embodiments described herein, switching power supplies are operated with a switching frequency that is modulated based on a function of the input signal. In various further embodiments, the switching frequency or other switching parameters are adjusted to control an output voltage, output current, or output power.

In various embodiments, a controller for a switching power supply determines the phase angle of an input signal. The input signal may be a rectified AC signal. Based on the phase angle, the controller modulates the switching frequency of the switching power supply using a function of the phase angle. In various different embodiments, the function of the phase angle may include saw tooth functions, polynomial functions, linear functions, hyperbolic functions, sinusoidal functions, or other functions, as described further hereinafter in reference to the figures. In such embodiments, modulation of the switching frequency as a function of phase angle of the input signal may reduce or eliminate flicker in lighting systems and may reduce EMI, THD, and energy per harmonic frequency in general systems. In additional embodiments, the controller modulates the switching frequency of the switching power supply using a function of the input signal, such as the frequency. In such embodiments, the function for modulating the switching frequency may include both the phase angle and the frequency of the input signal.

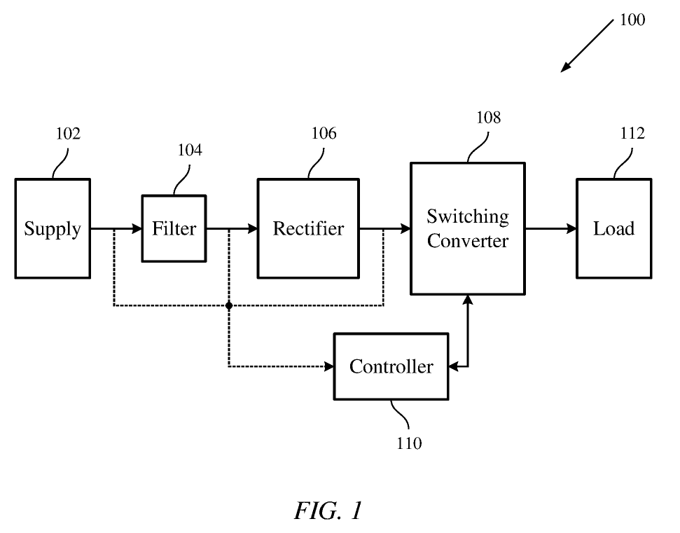

FIG. 1 illustrates a system block diagram of an embodiment switching power supply 100 including input supply 102, filter 104, rectifier 106, switching converter 108, controller 110, and load 112. According to various embodiments, input supply 102 provides power from a power source. In some embodiments, input supply 102 is an AC supply, such as from grid supplied power outlet. In particular, switching power supply 100 is arranged and described in reference to an AC supply. However, in some embodiments, input supply 102 may be a DC supply instead, such as a battery or fuel-cell. Various modifications may be readily appreciated by those of skill in the art. For example, rectifier 106 may be omitted when input supply 102 is a DC supply.

In various embodiments, input supply 102 provides an AC signal to filter 104, which provides a filtered AC signal to rectifier 106. Rectifier 106 generates a rectified periodic signal that is provided to switching converter 108. In various embodiments, controller 110 determines the phase angle of the AC signal. Controller 110 may determine the phase angle or AC frequency of the AC signal before or after rectification. In various different embodiments, controller 110 receives an input from input supply 102, filter 104, or rectifier 106 as shown by the dashed lines. Controller 110 determines the phase angle or AC frequency of the AC signal based on the input. In such embodiments, controller 110 may measure the voltage of the AC signal and determine the phase angle or AC frequency. Controller 110 also receives feedback signals from switching converter 108. The feedback signals may include, for example, a measure of current flowing in switching converter 108 or a measurement of voltage provided at an output of switching converter 108. Based on the measured input voltage, phase angle, AC frequency, or feedback signals, controller 110 generates a switching control signal for switching converter 108 in order to generate a desired output signal to supply load 112. For example, load 112 may include series connected LEDs in a lighting application. In various embodiments, the output signal may be a DC or an AC signal.

According to various embodiments, controller 110 generates the switching control signal with a switching frequency. In such embodiments, the switching frequency is modulated during the switching cycle. Specifically, the switching frequency is modulated using a function of the AC signal. In particular embodiments, the switching frequency is modulated using a function of the phase angle or AC frequency of the AC signal. The specific function used may include different function types as further described hereinafter in reference to the other figures. In some embodiments, controller 110 may modulate the switching period of the switching control signal provided to switching converter 108.

In various embodiments, controller 110 controls switching converter 108 using the switching control signal to supply a regulated output to load 112. For example, controller 110 may adjust a switching duty cycle to supply more or less current or voltage through switching converter 108 to load 112. In one further embodiment, controller 110 may control the average switching frequency to regulate the average power (or voltage or current) delivered to load 112. In such embodiments, controller 110 modulates the switching frequency in order to optimize the performance using the instantaneous power transfer, which has an average of 0.

Further, in some embodiments, controller 110 may control switching converter 108 to operate in different modes dependent on the output signal or the input signal. For example, in some embodiments, controller 110 may control switching converter 108 to operate in a discontinuous conduction mode (DCM) or a quasi-resonant mode (QRM). In alternative embodiments, controller 110 may also control switching converter 108 to operate in a continuous conduction mode (CCM). The modes of operation initiated by controller 110 may vary based on specific switching power supply applications, in some embodiments.

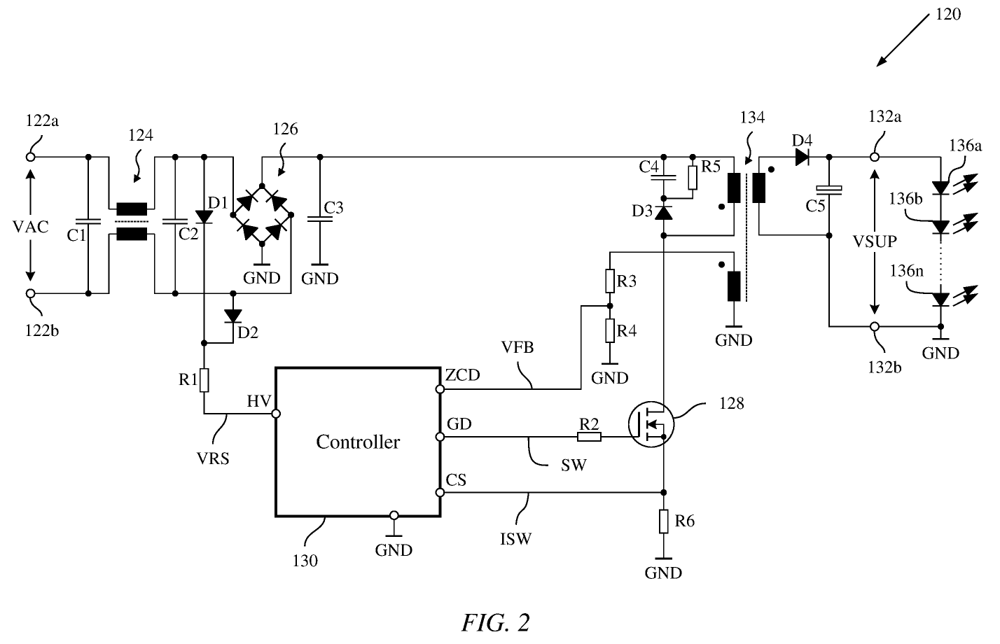

FIG. 2 illustrates a schematic diagram of an embodiment switching power supply 120 including input terminals 122a and 122b, filter 124, bridge rectifier 126, switching transistor 128, controller 130, output terminals 132a and 132b, transformer 134, and LEDs 136a, 136b, and 136n. According to various embodiments, switching power supply 120 may be one implementation of switching power supply 100 described hereinabove in reference to FIG. 1. Input terminals 122a and 122b receive AC input signal VAC, which is filtered by filter 124 and rectified by bridge rectifier 126.

According to various embodiments, controller 130 receives, through diode D1, diode D2, and resistor R1, rectified signal VRS at voltage input pin HV that corresponds to AC input signal VAC. Controller 130 also receives, as feedback signals, feedback voltage VFB and switch current ISW at zero crossing detection pin ZCD and current sense pin CS, respectively. In such embodiments, feedback voltage VFB is generated through a resistive divider circuit including resistor R3 and resistor R4, which are connected between a second primary side winding of transformer 134 and ground node GND. In some particular embodiments, ground node GND may have a reference potential that is other than earth ground. Controller 130 also may include a ground pin coupled to ground node GND, as shown.

A first primary side winding and a secondary side winding of transformer 134 provide isolation between the input side and the output side of switching power supply 120. The input side includes filter 124, bridge rectifier 126, switching transistor 128, and controller 130, and the output side provides supply voltage VSUP to LEDs 136a, 136b, . . . , and 136n. In such embodiments, any number of LEDs may be included and n corresponds to the number of LEDs included. For example, in embodiments where n=e, the number of LEDs included is five LEDs, which are indicated as LEDs 136a, 136b, 136c, 136d, and 136e.

According to various embodiments, controller 130 outputs switching signal SW at gate drive pin GD. Thus, controller 130 provides switching signal SW, through resistor R2, to switching transistor 128 in order to generate and regulate supply voltage VSUP provided at output terminals 132a and 132b. In various embodiments, switching signal SW includes a switching frequency fsw, and the corresponding switching period Tsw, and a duty cycle SW %. By varying duty cycle SW %, controller 130 is able to regulate supply voltage VSUP in order to provide more or less current or voltage to LEDs 136a, 136b, . . . , and 136n, depending on the system operation and application. In particular embodiments, controller 130 adjusts duty cycle SW % based on feedback voltage VFB received at zero crossing detection pin ZCD and switch current ISW received at current sense pin CS. In alternative embodiments, controller 130 may also adjust duty cycle SW % based on rectified signal VRS received at voltage input pin HV.

According to various embodiments, controller 130 also modulates switching frequency fsw of switching signal SW. Specifically, controller 130 modulates switching frequency fsw by applying a modulation function. The modulation function is a function of rectified signal VRS. In particular embodiments, the modulation function is a function of the phase angle of rectified signal VRS. In such embodiments, controller 130 applies the modulation function, which varies based on the phase angle of rectified signal VRS, to switching frequency fsw. In further embodiments, the modulation function may also be a function of the frequency of rectified signal VRS. In specific embodiments, the modulation function applied to switching frequency fsw may include saw tooth functions, polynomial functions, linear functions, hyperbolic functions, or sinusoidal functions. In still further embodiments, the modulation function applied to switching frequency fsw may include other functions.

In various embodiments, switching power supply 120 also includes various passive elements. For example, switching power supply 120 may include freewheeling diode D3 and output diode D4 to maintain current polarity in some embodiments. Input capacitors C1 and C2 may accompany filter 124. Output capacitor C5 may regulate or stabilize supply voltage VSUP. Further, input filter capacitor C3 along with a snubber formed by parallel connected resistor R5 and capacitor C4 may be coupled to an output of bridge rectifier 126 and an input of the first primary side winding of transformer 134. In various embodiments, switch current ISW may be measured as a voltage at current sense pin CS. In such embodiments, resistor R6 may be included in order to conduct switch current ISW and generate a voltage corresponding to switch current ISW. In various embodiments, such passive components may be rearranged to include fewer components or additional components. As will be readily appreciated by one having skill in the art, the impedance values of the various passive components will depend on the specific applications and may range across many values.

FIG. 3 illustrates a functional block diagram of an embodiment controller 140 for a switching power supply. According to various embodiments, controller 140 is one embodiment implementation of controller 130, or a portion of controller 130, in switching power supply 120 as described hereinabove in reference to FIG. 2. Controller 140 includes phase detection circuit 144, phase function circuit 146, dynamic controller 148, pulse width modulation (PWM) circuit 150, driver circuit 152, current sense circuit 154, and zero crossing detection (ZCD) circuit 156.

According to various embodiments, dynamic controller 148 provides switching control signal SWCTL to PWM circuit 150 in order to control switching. Switching control signal SWCTL may include information for generating pulse width modulated logical switching signal LSW. In particular embodiments, switching control signal SWCTL may include maximum switching on-time, minimum switching period, maximum switching period, duty cycle information, or zero crossing information. PWM circuit 150 uses the information included in switching control signal SWCTL to calculate the specific switching frequency and duty cycle used for controlling a switching transistor and generates pulse width modulated logical switching signal LSW based on the switching frequency and duty cycle calculated. In such embodiments, pulse width modulated logical switching signal LSW is provided to driver circuit 152, which generates a drive strength signal, switching signal SW, to drive a switching transistor coupled to gate drive pin GD.

In various embodiments, dynamic controller 148 generates switching control signal SWCTL based on feedback signal FB1 and feedback signal FB2 from current sense circuit 154 and ZCD circuit 156, respectively. Current sense circuit 154 generates switching current feedback information, feedback signal FB1, based on switch current ISW received at current sense pin CS. In such embodiments, switch current ISW may directly be a current measurement or may be a voltage measurement indicative of current. Based on switch current ISW, current sense circuit 154 generates the switching current feedback information for feedback signal FB1 as either digital or analog feedback. Similarly, ZCD circuit 156 generates zero crossing feedback information, feedback signal FB2, based on feedback voltage VFB received at zero crossing detection pin ZCD. Based on feedback voltage VFB, ZCD circuit 156 generates the zero crossing feedback information for feedback signal FB2 as either digital or analog feedback. ZCD circuit 156 may provide feedback signal FB2 to dynamic controller 148 and PWM circuit 150 in various embodiments. In a specific embodiment, during certain operation modes, PWM circuit 150 may operate based on feedback signal FB2 alone and bypass dynamic controller 148.

In such embodiments, dynamic controller 148 uses feedback signal FB1 and feedback signal FB2 to adjust the information included in switching control signal SWCTL. In some embodiments, dynamic controller 148 may adjust switching control signal SWCTL continuously. In other embodiments, dynamic controller 148 may adjust switching control signal SWCTL discretely with fixed or variable step sizes for incrementing the information included in switching control signal SWCTL. In some embodiments, dynamic controller 148 may be implemented as a proportional-integral-derivative (PID) controller.

In various embodiments, dynamic controller 148 also receives phase function F(Φ) from phase function circuit 146. In such embodiments, dynamic controller 148 generates switching control signal SWCTL in order to adjust or modulate switching frequency fsw and switching period Tsw of the switching transistor coupled to gate drive pin GD based on phase function F(Φ). Specifically, switching frequency fsw is modulated using phase function F(Φ).

According to various embodiments, phase detection circuit 144 receives rectified signal VRS from voltage input pin HV. Phase detection circuit 144 may include an analog-to-digital converter or a comparator that generates a digital rectified signal based thereon in some embodiments. In other alternative embodiments, phase detection circuit 144 may omit the ADC. Phase detection circuit 144 identifies phase angle Φ of rectified signal VRS, or the digital rectified signal, which corresponds to the phase angle of the input rectified signal for the switching power supply, such as switching power supply 120 as described hereinabove in reference to FIG. 2, for example. In such embodiments, because rectified signal VRS, and correspondingly the digital rectified signal, is rectified, rectified signal VRS repeats every 180°. In comparison, AC input signal VAC (FIG. 2) repeats every 360°. Thus, phase angle 1 indicates the phase of rectified signal VRS, and correspondingly the digital rectified signal, ranging from 0° to 180°. In various embodiments, phase detection circuit 144 may also detect the frequency of rectified signal VRS. For example, phase detection circuit 144 may include a comparator or multiple comparators with thresholds used for detecting rising and falling input signals. Based on the comparisons, a signal is generated for comparison to an oscillator signal in order to determine the frequency of rectified VRS.

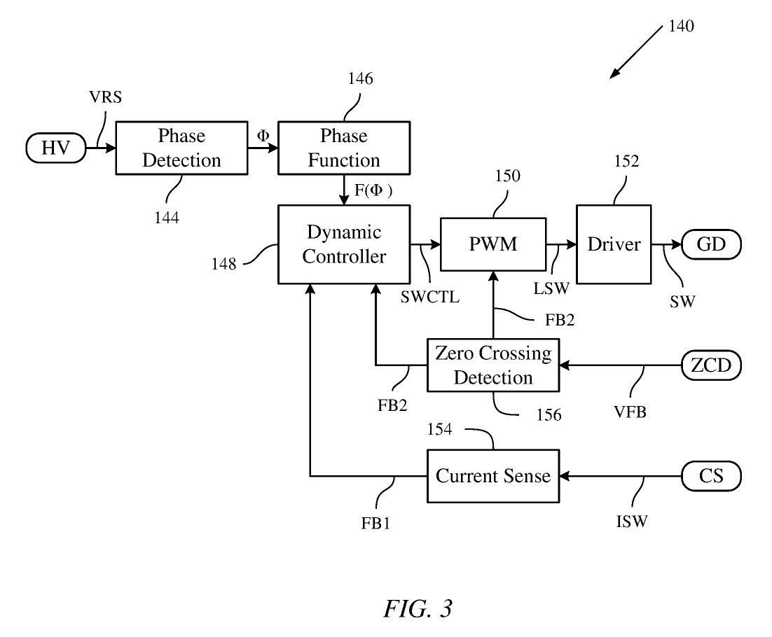

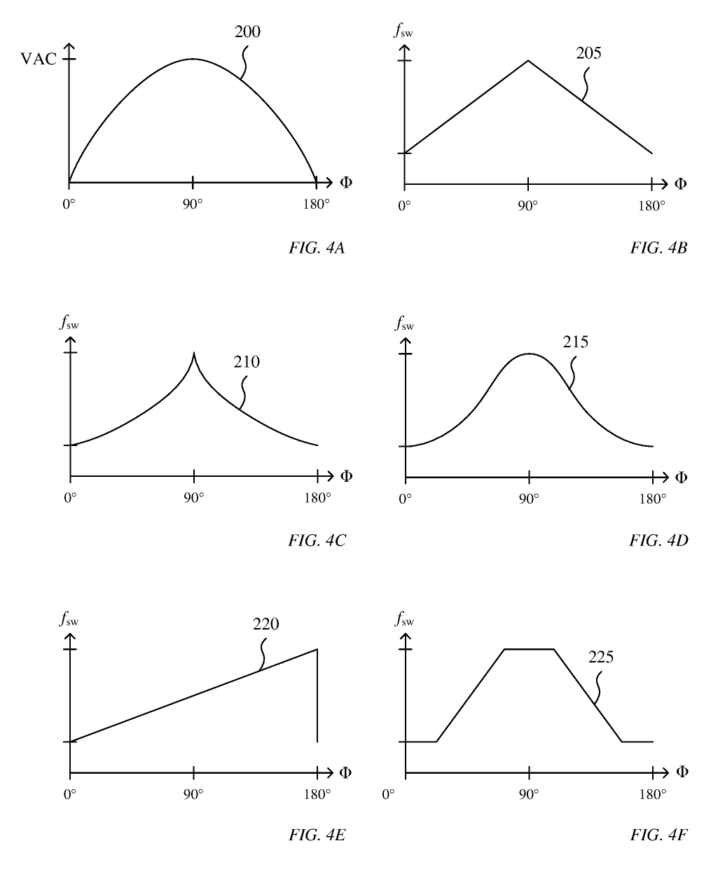

In such embodiments, phase function circuit 146 receives phase angle Φ from phase detection circuit 144 and generates phase function F(Φ), which may include various different function types. In some embodiments, phase function F(Φ) may be a function of phase angle 1 and input frequency. In a specific embodiment, phase function F(Φ) includes a saw tooth function of phase angle Φ. In another specific embodiment, phase function F(Φ) includes a polynomial function of phase angle Φ. In still another specific embodiment, phase function F(Φ) includes a linear function of phase angle Φ. In a further specific embodiment, phase function F(Φ) includes a hyperbolic function of phase angle Φ. In a still further specific embodiment, phase function F(Φ) includes a sinusoidal function of phase angle Φ. In yet another specific embodiment, phase function F(Φ) includes a combination of the above functions. In alternative embodiments, phase function F(Φ) includes other functions of phase angle Φ. In particular embodiments, any of the above functions may be asymmetric about 90° for phase angle Φ. In other particular embodiments, any of the above functions may be symmetric about 90° for phase angle Φ. Phase function circuit 146 may calculate phase function F(Φ) directly from phase angle Φ in some embodiments. In other embodiments, phase function circuit 146 may use a lookup table (LUT) using phase angle Φ to retrieve the values of phase function F(Φ). In various such embodiments, phase function F(Φ) may include a factor based on the input frequency that adjusts the behavior of phase function F(Φ). Further description of some specific embodiment phase functions F(Φ) are described hereinafter in reference to FIGS. 4B, 4C, 4D, 4E, and 4F.

In various embodiments, phase function circuit 146 may be implemented by a digital controller or processor as a digital circuit, such as in a digital signal processor (DSP). In other embodiments, phase function circuit 146 is implemented using discrete components and may be implemented using discrete analog circuit or digital logic circuit components.

In various further embodiments, controller 140 may be configured to drive multiple switching transistors. In such embodiments, various modifications will be readily apparent to those having skill in the art. For example, gate drive pin GD may include multiple gate drive pins and the feedback and control loop generating switching signals for each of the gate drive pins will be modified to generate the switching signals for each of the gate drive pins in a similar manner as described hereinabove. Further, various implementations of controller 140 may include all digital, all analog, and mixed analog and digital implementations. In particular embodiments, controller 140 is a digital controller. In some specific embodiments, controller 140 includes digital operation and digital components for all elements except driver circuit 152.

FIGS. 4A, 4B, 4C, 4D, 4E, and 4F illustrate waveform diagrams from an embodiment switching power supply. These waveform diagrams may correspond to switching power supply 100 or switching power supply 120 as described hereinabove in reference to FIGS. 1 and 2. The waveforms illustrated in FIGS. 4A, 4B, 4C, 4D, 4E, and 4F include voltage waveform 200 and switching frequency waveforms 205, 210, 215, 220, and 225. According to various embodiments, voltage waveform 200 illustrates an input voltage for an embodiment power supply. As shown, voltage waveform 200 ranges in magnitude as a function of phase angle Φ from 0° to 180°. In some embodiments, voltage waveform 200 is a rectified AC input signal. Due to the rectification, the signal repeats every 180°.

FIGS. 4B, 4C, 4D, 4E, and 4F illustrate switching frequency waveforms 205, 210, 215, 220, and 225 that correspond to voltage waveform 200 according to different embodiment phase functions F(Φ). Switching frequency waveform 205 illustrates a phase function F(Φ) that adjusts switching frequency fsw as a triangle function of phase angle Φ in accordance with one embodiment. Switching frequency waveform 210 illustrates a phase function F(Φ) that adjusts switching frequency fsw as a polynomial function of phase angle Φ in accordance with another embodiment. Switching frequency waveform 215 illustrates a phase function F(Φ) that adjusts switching frequency fsw as a sinusoidal function of phase angle Φ in accordance with yet another embodiment. Switching frequency waveform 220 illustrates a phase function F(Φ) that adjusts switching frequency fsw as a saw tooth function of phase angle Φ in accordance with a further embodiment. Switching frequency waveform 225 illustrates a phase function F(Φ) that adjusts switching frequency fsw as a triangle function of phase angle Φ that includes maximum and minimum switching frequency fsw limits in accordance with a yet further embodiment.

According to various embodiments, each of switching frequency waveforms 205, 210, 215, 220, and 225 repeats every 180° of phase angle Φ from voltage waveform 200. Switching frequency waveforms 205, 210, 215, and 225 illustrate embodiment phase functions F(Φ) that are symmetric about a phase angle Φ of 90°, while Switching frequency waveform 220 illustrates an embodiment phase function F(Φ) that is asymmetric about a phase angle Φ of 90°. In various further embodiments, phase functions F(Φ) may be shifted to be asymmetric about a phase angle Φ of 90°. In some embodiments, the variation of switching frequency fsw may range across a narrow frequency range such as from 0 to 2 kHz above or below the base switching frequency. In other embodiments, the variation of switching frequency fsw may range across a broader frequency range such as from 0 to 50 kHz above or below the base switching frequency. Although not explicitly illustrated, some embodiments may include a phase function F(Φ) that adjusts switching frequency fsw as a hyperbolic function of phase angle Φ. Further, additional embodiments may include a phase function F(Φ) that adjusts switching frequency fsw as a combination of the different functions of phase angle Φ described herein. In alternative embodiments, phase function F(Φ) adjusts switching frequency fsw using other functions of phase angle Φ.

In particular embodiments, different characteristics of phase function F(Φ) used for modulating switching frequency fsw may improve different performance criteria. For example, in some specific embodiments, using a function that is asymmetric about a phase angle Φ of 90° may advantageously improve power factor correction (PFC). In another specific embodiment, using a function that is symmetric about a phase angle Φ of 90° may advantageously reduce total harmonic distortion (THD). In still another specific embodiment, using a function that modulates switching frequency fsw over a larger frequency range may reduce effects from electromagnetic interference (EMI). In various embodiments, phase function F(Φ) may be applied to modulate switching frequency fsw continuously. In other embodiments, phase function F(Φ) may be applied to modulate switching frequency fsw using discrete steps.

In various embodiments, the frequency of the AC input signal may also be used in phase function F(Φ). Specifically, various embodiments may determine the frequency of the AC input signal and adjust phase function F(Φ) based on the frequency. In particular embodiments, some AC input signal frequencies may produce more significant THD issues and some AC input signal frequencies may produce more significant power factor issues. For example, different countries throughout the world currently use different frequency AC power systems that exhibit different issues more dominantly. For example, PFC may be more relevant in the USA while THD may be more relevant in Europe. In various such embodiments, the frequency of the AC input signal may be determined and the phase function F(Φ) may be adjusted based on the frequency of the AC input signal. The phase function F(Φ) may specifically include input frequency as a variable in the function. In such embodiments, switching frequency fsw is modulated differently based on different AC input signal frequencies.

According to various embodiments, phase function F(Φ) is synchronous or in phase with phase angle Φ. In specific embodiments, phase function F(Φ) is applied in phase with the fundamental frequency of phase angle Φ as illustrated in FIGS. 4B, 4C, 4D, 4E, and 4F. In further specific embodiments, phase function F(Φ) is applied in phase with the first harmonic of phase angle Φ. In still further specific embodiments, phase function F(Φ) is applied in phase with the second or higher harmonic of phase angle Φ.

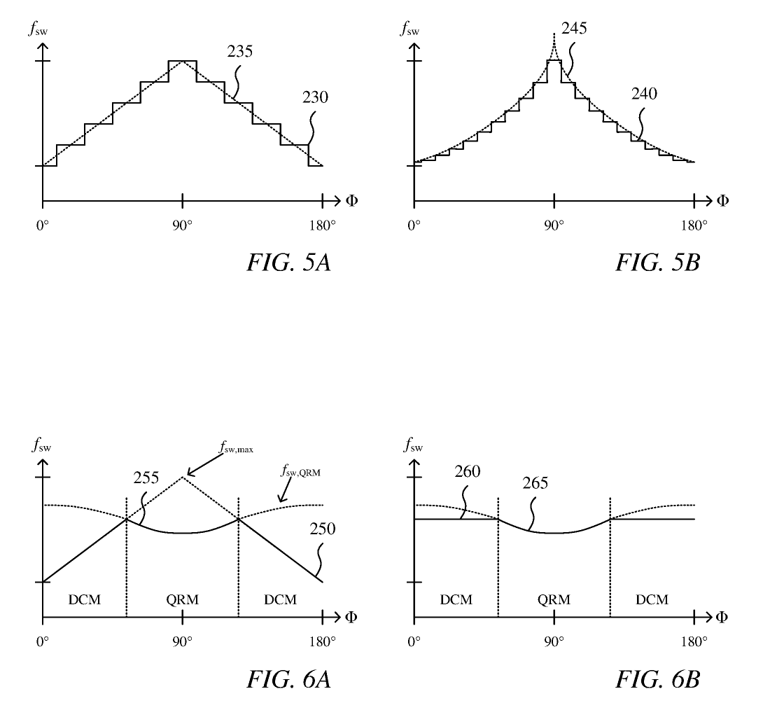

FIGS. 5A and 5B illustrate waveform diagrams from another embodiment switching power supply. These waveform diagrams may correspond to switching power supply 100 or switching power supply 120 as described hereinabove in reference to FIGS. 1 and 2. The waveforms illustrated in FIGS. 5A and 5B include switching frequency waveforms 230, 235, 240, and 245. According to various embodiments, switching frequency waveform 235 illustrates a continuous target phase function F(Φ) and switching frequency waveform 230 illustrates a discrete phase function F(Φ) that approximates the continuous target phase function F(Φ) of switching frequency waveform 235. In such embodiments, the continuous target phase function F(Φ) of switching frequency waveform 235 is a triangle function of phase angle Φ and the discrete phase function F(Φ) of switching frequency waveform 230 uses moderate sized steps to approximate the triangle function.

According to another embodiment, switching frequency waveform 245 illustrates a continuous target phase function F(Φ) and switching frequency waveform 240 illustrates a discrete phase function F(Φ) that approximates the continuous target phase function F(Φ) of switching frequency waveform 245. In such embodiments, the continuous target phase function F(Φ) of switching frequency waveform 245 is a polynomial function of phase angle Φ and the discrete phase function F(Φ) of switching frequency waveform 240 uses smaller sized steps, as compared to switching frequency waveform 230, to approximate the polynomial function.

According to various embodiments, any of the phase functions F(Φ) described hereinabove, such as in reference to FIGS. 3, 4B, 4C, 4D, 4E, and 4F, for example, may be implemented using discrete steps as shown in FIGS. 5A and 5B.

FIGS. 6A and 6B illustrate waveform diagrams from a further embodiment switching power supply. These waveform diagrams may correspond to switching power supply 100 or switching power supply 120 as described hereinabove in reference to FIGS. 1 and 2. According to various embodiments, the waveform diagram of FIG. 6A includes switching frequency waveforms 250 and 255 corresponding to two different modes of operation. In such embodiments, the switching power supply operates in two modes, discontinuous conduction mode (DCM) and quasi-resonant mode (QRM). In such embodiments, the switching power supply may switch between DCM and QRM directly or indirectly based on certain conditions, e.g., phase angle Φ of an input signal for the power supply, such as AC input signal VAC described hereinabove in reference to FIG. 2. In other embodiments, the switching power supply switches between DCM and QRM and vice versa based on exceeding thresholds of switching frequency, on-duration, or primary peak-current.

During DCM, the switching power supply may modulate the switching frequency according to phase function F(Φ), as described hereinabove in reference to the other figures. Thus, switching frequency waveform 250 illustrates a phase function F(Φ) that adjusts switching frequency fsw as a triangle function of phase angle Φ in accordance with one embodiment. Any of the embodiment functions described hereinabove in reference to FIGS. 3, 4B, 4C, 4D, 4E, 4F, 5A, and 5B may be applied during DCM in such embodiments. In such embodiments, a controller, such as controller 110, controller 130, or controller 140 as described hereinabove in reference to FIGS. 1, 2, and 3, controls the switching transistor according to a discontinuous conduction scheme by adjusting the switching duty cycle in order to control the output of the switching power supply. At the same time, the controller also modulates switching frequency fsw according to phase function F(Φ).

During QRM, the switching power supply is switched according to a quasi-resonant scheme in order to improve efficiency. Quasi-resonant switching is a special case of discontinuous conduction mode (DCM) for which the switch is turned on at or near a valley time of the oscillation of transformer voltage during the off-phase of the switch. In such embodiments, during QRM the controller may suspend modulation of switching frequency fsw according to phase function F(Φ) and instead control switching in accordance with the quasi-resonant scheme. In such embodiments, the controller may control the switching transistor to turn on at a voltage valley following switching in accordance with the quasi-resonant scheme. Thus, switching frequency waveform 255 illustrates an embodiment switching frequency control function for application during QRM and switching frequency waveform 250 illustrates an embodiment switching frequency modulation function for application during DCM. Those of skill in the art will readily appreciate the application of QRM and DCM with various switching power supplies according to applications of various embodiments described herein.

According to an alternative approach, switching frequency fsw is maintained at a fixed frequency during DCM as illustrated by switching frequency waveform 260 in FIG. 6B. The switching power supply is operated according to the quasi-resonant scheme during QRM, which corresponds to the application of switching frequency waveform 265 to control switching frequency fsw.

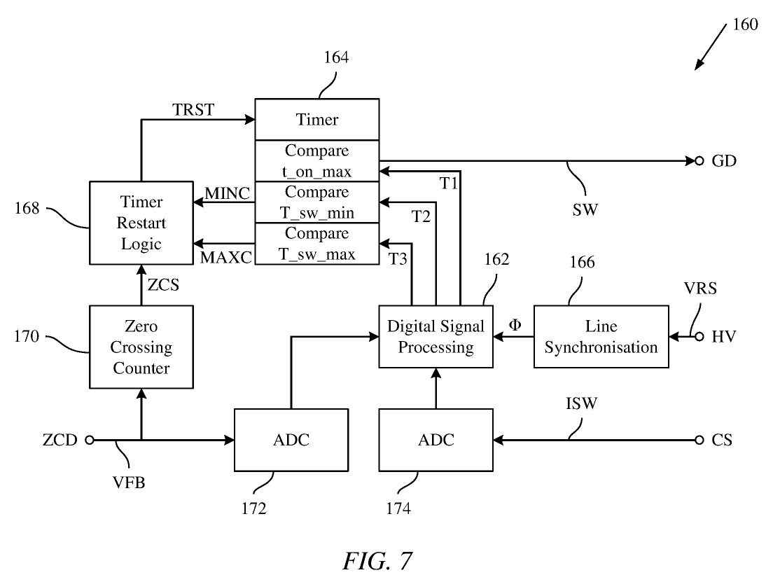

FIG. 7 illustrates a functional block diagram of another embodiment controller 160 for a switching power supply. According to various embodiments, controller 160 is another embodiment implementation of controller 130, or a portion of controller 130, in switching power supply 120 as described hereinabove in reference to FIG. 2. In such embodiments, controller 160 includes digital signal processing (DSP) circuit 162, timer circuit 164, line synchronization circuit 166, timer restart logic 168, zero crossing counter 170, analog-to-digital converter (ADC) 172, and ADC 174. Timer circuit 164 generates switching signal SW and provides it to gate drive output pin GD. In such embodiments, a driver circuit, such as driver circuit 152 as described hereinabove in reference to FIG. 3, may be included between timer circuit 164 and gate drive output pin GD. In various embodiments, ADC 172 and ADC 174 may be combined into a single ADC. In such embodiments, the single ADC may be shared by, for example, multiplexing the inputs from current sense pin CS and zero crossing detection pin ZCD to the single ADC.

According to various embodiments, timer circuit 164 generates switching signal SW by iteratively updating maximum switching on-time t_on_max, minimum switching period T_sw_min, and maximum switching period T_sw_max. In such embodiments, timer circuit 164 receives timer control signals T1, T2, and T3 from DSP circuit 162 that are used to iteratively update maximum switching on-time t_on_max, minimum switching period T_sw_min, and maximum switching period T_sw_max, respectively. Timer circuit 164 includes a timer and comparator circuits for generating timing and comparing the generated timing to maximum switching on-time t_on_max, minimum switching period T_sw_min, and maximum switching period T_sw_max. In some embodiments, timer circuit 164 includes three separate comparators. In other embodiments, timer circuit 164 includes a single comparator that uses multiplexing to perform three comparisons.

According to various embodiments, controller 160 operates in two modes, QRM and DCM, as similarly described hereinabove in reference to FIG. 6A. DSP circuit 162 iteratively updates maximum switching on-time t_on_max, minimum switching period T_sw_min, or maximum switching period T_sw_max based on the mode of operation and according to two primary considerations: (1) control of output power P_out, output current I_out, or output voltage V_out (such as supply voltage VSUP, for example) and (2) modulation of switching frequency fsw.

During DCM, DSP circuit 162 adjusts minimum switching period T_sw_min in order to control output power P_out delivered to a load (not shown, see FIG. 1) supplied by the switching power supply. In such embodiments, DSP circuit 162 may adjust timer control signal T2 based on a function of switch current ISW received from current sense pin CS (which is provided to DSP circuit 162 through ADC 174) and a target switch current. In other embodiments, other measures of output power P_out may be used by DSP circuit 162 to adjust timer control signal T2 for regulating output power P_out using minimum switching period T_sw_min during DCM. In such embodiments, DSP circuit 162 may hold maximum switching on-time t_on_max constant during DCM.

During QRM, DSP circuit 162 adjusts maximum switching on-time t_on_max in order to control output power P_out delivered to the load (not shown, see FIG. 1). In such embodiments, DSP circuit 162 may adjust timer control signal T1 based on a function of switch current ISW received from current sense pin CS and a target switch current. In other embodiments, other measures of output power P_out may be used by DSP circuit 162 to adjust timer control signal T1 for regulating output power P_out using maximum switching on-time t_on_max during QRM. In such embodiments, DSP circuit 162 may hold minimum switching period T_sw_min constant during QRM. In both QRM and DCM, DSP circuit 162 may hold maximum switching period T_sw_max constant. In various embodiments, maximum switching period T_sw_max (corresponding to minimum switching frequency) is set to maintain operation above a frequency range that is not desired, such as to avoid audible noise, for example. In such embodiments, the minimum switching frequency (corresponding to maximum switching period T_sw_max) should be above 18 kHz, for example, in order to avoid audible noises.

In various embodiments, DSP circuit 162 adds an offset to minimum switching period T_sw_min during DCM in order to modulate switching frequency fsw. In such embodiments, the offset added to minimum switching period T_sw_min is a function of phase angle Φ. In further embodiments, the offset added to minimum switching period T_sw_min is also a function of AC input frequency. The phase function F(Φ) used as an offset for minimum switching period T_sw_min may include any of the functions described hereinabove for phase function F(Φ) in reference to the other Figures, such as e.g., FIGS. 3, 4B, 4C, 4D, 4E, and 4F. Using phase function F(Φ), DSP circuit 162 adds the offset to minimum switching period T_sw_min in order to implement modulation of switching frequency fsw during DCM.

In various embodiments, line synchronization circuit 166 determines phase angle 41) based on rectified signal VRS received from voltage input pin HV, and provides phase angle 1 to DSP circuit 162. Line synchronization circuit 166 may also determine the AC input frequency based on rectified signal VRS. As described hereinabove, phase angle Φ may range from 0° to 180° with phase function F(Φ) repeating every 180° cycle. In some embodiments, DSP circuit 162 may directly calculate values for phase function F(Φ) based on phase angle Φ. In other embodiments, DSP circuit 162 may use a lookup table (LUT) to retrieve values of phase function F(Φ) based on phase angle Φ. The LUT may be included within DSP circuit 162 or may be an additional component (not shown).

According to various embodiments, timer circuit 164 generates switching signal SW as a pulse width modulated (PWM) signal using maximum switching on-time t_on_max, minimum switching period T_sw_min, or maximum switching period T_sw_max, which are iteratively updated based on the mode of operation (DCM or QRM) of controller 160. In such embodiments, timer circuit 164 operates with timer restart logic 168 to control on-time and off-time of switching signal SW according to the following description. Timer circuit 164 asserts, i.e., turns on, switching signal SW at a restart of each switching cycle, which is initiated by timer reset signal TRST from timer restart logic 168. Following asserting switching signal SW, timer circuit 164 de-asserts, i.e., turns off, switching signal SW when maximum switching on-time t_on_max is exceeded. In some embodiments, timer circuit 164 may also de-assert switching signal SW if a maximum peak current is exceeded. Protection from overcurrent or peak current control may be implemented in the switching power supply using additional components known by those having skill the art and will not be further described herein in the interest of brevity.

In various embodiments, timer circuit 164 continues incrementing the timer until a restart of the switching cycle is initiated by timer reset signal TRST. Timer restart logic 168 generates timer reset signal TRST in order to restart the switching cycle based on zero crossing signal ZCS, minimum switching period comparison MINC, and maximum switching comparison MAXC. In various embodiments, feedback voltage VFB from zero crossing detection pin ZCD may exhibit some oscillations, with voltage peaks (local maxima) and voltage valleys (local minima), after each instance of switching. Zero crossing counter 170 generates zero crossing signal ZCS in order to indicate the occurrence of voltage valleys. QRM includes switching at or close to a target voltage valley. In various embodiments, switching power supplies may operate with a target valley that is the first voltage valley, the second voltage valley, the third voltage valley, and so on, depending on the control scheme used by various switching power supplies.

In such various embodiments, when the target valley occurs, as indicated by zero crossing signal ZCS, before minimum switching period T_sw_min, as indicated by minimum switching period comparison MINC, timer restart logic 168 will initiate a restart of the switching cycle once minimum switching period T_sw_min is reached. Such embodiments may correspond to operation in DCM. Conversely, when the target valley occurs after minimum switching period T_sw_min, timer restart logic 168 will initiate a restart of the switching cycle once the target valley is reached. Such embodiments may correspond to operation in QRM.

In various embodiments, in either QRM or DCM, when the target valley does not occur before maximum switching period T_sw_max, as indicated by maximum switching period comparison MAXC, timer restart logic 168 will initiate a restart of the switching cycle once maximum switching period T_sw_max is reached. In such embodiments, switching frequency fsw is limited to a minimum that corresponds to maximum switching period T_sw_max. In various embodiments, DSP circuit 162 may control and update any of maximum switching on-time t_on_max, minimum switching period T_sw_min, or maximum switching period T_sw_max using timer control signals T1, T2, and T3 based on feedback voltage VFB (received through ADC 172), switch current ISW, and phase angle Φ.

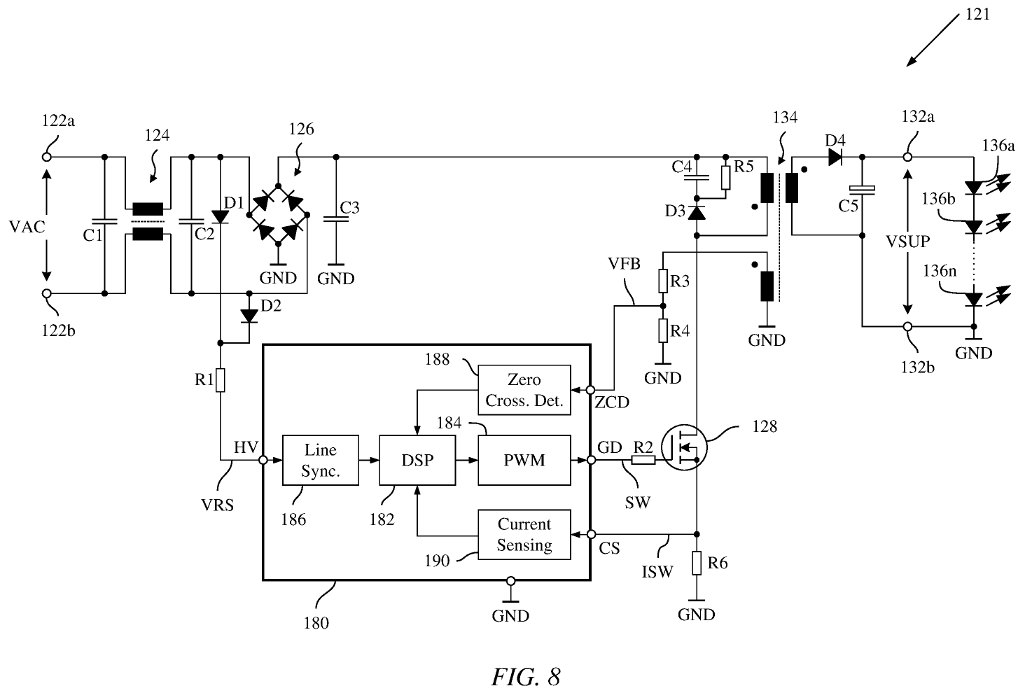

FIG. 8 illustrates a schematic diagram of still another embodiment switching power supply 121, which may be an implementation of switching power supply 120 as described hereinabove in reference to FIG. 2. In such embodiments, controller 130 is implemented with control system 180 including line synchronization circuit 186, DSP circuit 182, PWM circuit 184, zero crossing detection circuit 188, and current sensing circuit 190. In such embodiments, control system 180 may include discrete components for each of line synchronization circuit 186, DSP circuit 182, PWM circuit 184, zero crossing detection circuit 188, and current sensing circuit 190. In other embodiments, control system 180 may include an integrated circuit that includes each of line synchronization circuit 186, DSP circuit 182, PWM circuit 184, zero crossing detection circuit 188, and current sensing circuit 190 integrated in the same semiconductor die. According to various embodiments, control system 180 may implement any of the functions described hereinabove in reference to controller 140 or controller 160 in FIG. 3 and FIG. 7, respectively.

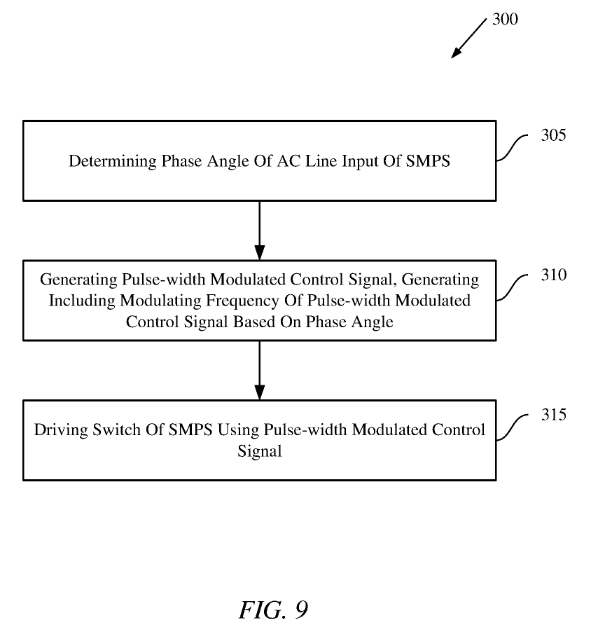

FIG. 9 illustrates a flowchart diagram of an embodiment method 300 of operating a switching circuit. Method 300 includes steps 305, 310, and 315. According to various embodiments, step 305 includes determining a phase angle of an AC line input of the SMPS. The input signal has an AC input voltage, and may be received from a grid supplied power plug. In such embodiments, the AC line input may have a phase angle ranging from 0° to 360°. In particular embodiments, the AC line input may be rectified and, consequently, the phase angle may range from 0° to 180°.

In various embodiments, step 310 includes generating a pulse-width modulated control signal. In such embodiments, generating the pulse-width modulated control signal includes modulating the frequency of the pulse-width modulated control signal based on the phase angle determined in step 305. In some embodiments, the phase angle is used as a function variable in order to calculate a frequency modulation value as a function of the phase angle. In various specific embodiments, the function of the phase angle may include numerous function types, as described hereinabove in reference to the other figures, such as FIGS. 4B, 4C, 4D, 4E, and 4F. In various embodiments, the frequency modulation is applied synchronous or in phase with the AC line input. In specific embodiments, the frequency modulation is applied in phase with the fundamental frequency of the AC line input. In other specific embodiments, the frequency modulation is applied in phase with the first harmonic of the AC line input. In still further specific embodiments, the frequency modulation is applied in phase with the second or higher harmonic of the AC line input.

In various embodiments, step 315 includes driving a switch of the SMPS using the pulse-width modulated control signal of step 310. The pulse-width modulated control signal controls the switch, which in turn generates and regulates an output signal of the SMPS to supply a load. In such embodiments, the duty cycle or average switching frequency of the switching may be controlled in order to regulate the supply signal, e.g., voltage, at the output of the SMPS. By adjusting the duty cycle or average switching frequency of the switching, e.g., based on feedback signals, the supply signal at the output of the SMPS may be regulated to a specific output voltage, output current, or output power.

In various embodiments, additional steps may be included in method 300. Further, in alternative embodiments, step 305, step 310, and step 315 may be performed in a different order than described herein.

According to an embodiment, a switched-mode power supply (SMPS) includes a controller including a measurement circuit and a pulse width modulator having an output configured to be coupled to a control node of a switch of the SMPS. The measurement circuit is configured to determine a phase angle of an AC line input of the SMPS and modulate a frequency of a control signal at the output of the pulse width modulator based on the phase angle.

In various embodiments, the measurement circuit is further configured to determine an AC frequency of the AC line input of the SMPS and modulate the frequency of the control signal at the output of the pulse width modulator based on the AC frequency of the AC line input. In some embodiments, the SMPS further includes a rectifier coupled between the AC line input and an input of the measurement circuit. The phase angle of an AC line input of the SMPS may be determined based on measuring a current or voltage from a transformer winding in the SMPS. In further embodiments, the phase angle of an AC line input of the SMPS is determined based on measuring a voltage of the AC line input through a resistor circuit coupled between the AC line input and an input of the measurement circuit.

In various embodiments, the controller is disposed on an integrated circuit. In some embodiments, the controller is further configured to modulate the frequency of the control signal based on a function of the phase angle. In such embodiments, the function of the phase angle may also be a function of an AC frequency of the AC line input of the SMPS. In further embodiments, the function of the phase angle repeats every 180° of the phase angle.

In particular embodiments, the function of the phase angle is a saw tooth function. In other embodiments, the function of the phase angle is a polynomial function. In additional embodiments, the function of the phase angle is a linear function. In some embodiments, the function of the phase angle is a hyperbolic function. In further embodiments, the function of the phase angle is a sinusoidal function. In still further embodiments, the function of the phase angle is a digital function that modulates the frequency of the control signal according to discrete frequency steps. In still additional embodiments, the function of the phase angle includes a minimum limit and a maximum limit for the frequency of the control signal.

In various embodiments, the SMPS further includes the switch. In such embodiments, the SMPS further includes a rectifier coupled between the AC line input and the switch and an inductive element coupled to the switch. In further embodiments, the controller is configured to operate in a first mode and in a second mode. In such embodiments, in the first mode, the controller modulates the frequency of the control signal based on a function of the phase angle, and, in the second mode, the controller generates the control signal according to a quasi-resonant mode of operation.

According to an embodiment, a method of operating a switched-mode power supply (SMPS) includes determining a phase angle of an AC line input of the SMPS, generating a pulse-width modulated control signal, and driving a switch of the SMPS using the pulse-width modulated control signal. Generating the pulse-width modulated control signal includes modulating a frequency of the pulse-width modulated control signal based on the phase angle.

In various embodiments, the method further includes determining an AC frequency of the AC line input of the SMPS and modulating the frequency of the pulse-width modulated control signal based the AC frequency. In some embodiments, the method further includes rectifying the AC line input before determining the phase angle.

In various embodiments, modulating the frequency of the pulse-width modulated control signal includes modulating the frequency of the pulse-width modulated control signal based on a function of the phase angle. In such embodiments, the function of the phase angle repeats every 180° of the phase angle. In further embodiments, the function of the phase angle includes one or more functions from a list consisting of a saw tooth function, a polynomial function, a linear function, a hyperbolic function, a sinusoidal function, and a digital function that modulates the frequency of the pulse-width modulated control signal according to discrete frequency steps. In additional embodiments, the function of the phase angle includes a minimum limit and a maximum limit for the frequency of the pulse-width modulated control signal.

In various embodiments, modulating the frequency of the pulse-width modulated control signal includes adjusting the frequency of the pulse-width modulated control signal according to a first mode of operation and a second mode of operation. In such embodiments, the first mode of operation includes modulating the frequency of the pulse-width modulated control signal based on a function of the phase angle, and, in such embodiments, the second mode of operation includes adjusting the frequency and duty-cycle of the pulse-width modulated control signal according to a quasi-resonant mode of operation.

According to an embodiment, a switched-mode power supply (SMPS) includes a controller integrated circuit (IC) including a phase measurement circuit coupled to a rectified input terminal of the controller IC, a pulse width modulator having an output configured to be coupled to a control terminal of a switching transistor, and a digital control circuit having an input coupled to the phase measurement circuit and an output coupled to the pulse width modulator. The digital control circuit is configured to modulate a frequency of a gate drive signal produced at the output of the pulse width modulator based on a phase measurement by the phase measurement circuit.

In various embodiments, the digital control circuit is further configured to modulate the frequency of the gate drive signal produced at the output of the pulse width modulator based on an AC frequency of the rectified input terminal of the controller IC determined by the phase measurement circuit. In such embodiments, the output of the pulse width modulator is coupled to a gate drive terminal of the controller IC. In further embodiments, the SMPS further includes the switching transistor with the control terminal coupled to the gate drive terminal. The SMPS may further include a rectifier coupled between an AC line input and the rectified input terminal of the controller IC and an inductive element coupled to the switching transistor. In additional embodiments, the SMPS further includes a plurality of series connected LEDs coupled to the inductive element.

In various embodiments, the digital control circuit is configured to modulate the frequency of the gate drive signal based on a function of the phase measurement, where the function of the phase measurement includes one or more functions from a list including a saw tooth function, a polynomial function, a linear function, a hyperbolic function, a sinusoidal function, and a digital function that modulates the frequency of the gate drive signal according to discrete frequency steps. In some embodiments, modulating the frequency of the gate drive signal includes adjusting the gate drive signal according to a first mode of operation and a second mode of operation. In such embodiments, the first mode of operation includes modulating the frequency of the gate drive signal according to a function of the phase measurement, and, in such embodiments, the second mode of operation includes adjusting the gate drive signal according to a quasi-resonant mode of operation.

Various embodiment switching power supplies or converters described herein that include modulation of switching frequency according to embodiments may advantageously include reduced THD, reduced energy per harmonic frequency, and reduced EMI. In embodiment switching power supplies for supplying lighting applications, such as with LEDs, the quality of the light may be improved, such as through the reduction of flicker. In some particular embodiments, modulating the switching frequency of an embodiment switching power supply using an asymmetric function of phase angle may advantageously improve PFC. In additional particular embodiments, modulating the switching frequency of an embodiment switching power supply using a symmetric function of phase angle may advantageously reduce THD. In further particular embodiments, modulating the switching frequency of an embodiment switching power supply over a larger frequency range may advantageously reduce EMI.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A switched-mode power supply (SMPS) comprising:
a controller comprising
a pulse width modulator having an output configured to be coupled to a control node of a switch of the SMPS, and
a measurement circuit configured to
determine a phase angle of an AC line input of the SMPS, and
modulate a frequency of a control signal at the output of the pulse width modulator based on the phase angle.

2. The SMPS of claim 1, wherein the measurement circuit is further configured to
determine an AC frequency of the AC line input of the SMPS, and
modulate the frequency of the control signal at the output of the pulse width modulator based on the AC frequency of the AC line input.

3. The SMPS of claim 1, further comprising a rectifier coupled between the AC line input and an input of the measurement circuit.

4. The SMPS of claim 1, wherein the phase angle of an AC line input of the SMPS is determined based on measuring a current or voltage from a transformer winding in the SMPS.

5. The SMPS of claim 1, wherein the phase angle of an AC line input of the SMPS is determined based on measuring a voltage of the AC line input through a resistor circuit coupled between the AC line input and an input of the measurement circuit.

6. The SMPS of claim 1, wherein the controller is disposed on an integrated circuit.

7. The SMPS of claim 1, wherein the controller is further configured to modulate the frequency of the control signal based on a function of the phase angle.

8. The SMPS of claim 7, wherein the function of the phase angle is also a function of an AC frequency of the AC line input of the SMPS.

9. The SMPS of claim 7, wherein the function of the phase angle repeats every 180° of the phase angle.

10. The SMPS of claim 7, wherein the function of the phase angle is a saw tooth function.

11. The SMPS of claim 7, wherein the function of the phase angle is a polynomial function.

12. The SMPS of claim 7, wherein the function of the phase angle is a linear function.

13. The SMPS of claim 7, wherein the function of the phase angle is a hyperbolic function.

14. The SMPS of claim 7, wherein the function of the phase angle is a sinusoidal function.

15. The SMPS of claim 7, wherein the function of the phase angle is a digital function that modulates the frequency of the control signal according to discrete frequency steps.

16. The SMPS of claim 7, wherein the function of the phase angle includes a minimum limit and a maximum limit for the frequency of the control signal.

17. The SMPS of claim 1, further comprising the switch.

18. The SMPS of claim 17, further comprising:
a rectifier coupled between the AC line input and the switch; and
an inductive element coupled to the switch.

19. The SMPS of claim 1, wherein:
the controller is configured to operate in a first mode and in a second mode;
in the first mode, the controller modulates the frequency of the control signal based on a function of the phase angle; and
in the second mode, the controller generates the control signal according to a quasi-resonant mode of operation.

20. A method of operating a switched-mode power supply (SMPS) comprising:
determining a phase angle of an AC line input of the SMPS;
generating a pulse-width modulated control signal, generating comprising modulating a frequency of the pulse-width modulated control signal based on the phase angle; and
driving a switch of the SMPS using the pulse-width modulated control signal.

21. The method of claim 20, further comprising:
determining an AC frequency of the AC line input of the SMPS; and
modulating the frequency of the pulse-width modulated control signal based the AC frequency.

22. The method of claim 20, further comprising rectifying the AC line input before determining the phase angle.

23. The method of claim 20, wherein modulating the frequency of the pulse-width modulated control signal comprises modulating the frequency of the pulse-width modulated control signal based on a function of the phase angle.

24. The method of claim 23, wherein the function of the phase angle repeats every 180° of the phase angle.

25. The method of claim 23, wherein the function of the phase angle comprises one or more functions from a list consisting of:
a saw tooth function;
a polynomial function;
a linear function;
a hyperbolic function;
a sinusoidal function; and
a digital function that modulates the frequency of the pulse-width modulated control signal according to discrete frequency steps.

26. The method of claim 23, wherein the function of the phase angle includes a minimum limit and a maximum limit for the frequency of the pulse-width modulated control signal.

27. The method of claim 20, wherein modulating the frequency of the pulse-width modulated control signal comprises adjusting the frequency of the pulse-width modulated control signal according to a first mode of operation and a second mode of operation, wherein
the first mode of operation comprises modulating the frequency of the pulse-width modulated control signal based on a function of the phase angle; and
the second mode of operation comprises adjusting the frequency and duty-cycle of the pulse-width modulated control signal according to a quasi-resonant mode of operation.

28. A switched-mode power supply (SMPS) comprising:
a controller integrated circuit (IC) comprising:
a phase measurement circuit coupled to a rectified input terminal of the controller IC,
a pulse width modulator having an output configured to be coupled to a control terminal of a switching transistor, and
a digital control circuit having an input coupled to the phase measurement circuit and an output coupled to the pulse width modulator, the digital control circuit configured to modulate a frequency of a gate drive signal produced at the output of the pulse width modulator based on a phase measurement by the phase measurement circuit.

29. The SMPS of claim 28, wherein the digital control circuit is further configured to modulate the frequency of the gate drive signal produced at the output of the pulse width modulator based on an AC frequency of the rectified input terminal of the controller IC determined by the phase measurement circuit.

30. The SMPS of claim 29, wherein the output of the pulse width modulator is coupled to a gate drive terminal of the controller IC.

31. The SMPS of claim 30, further comprising the switching transistor with the control terminal coupled to the gate drive terminal.

32. The SMPS of claim 31, further comprising:
a rectifier coupled between an AC line input and the rectified input terminal of the controller IC; and
an inductive element coupled to the switching transistor.

33. The SMPS of claim 32, further comprising a plurality of series connected LEDs coupled to the inductive element.

34. The SMPS of claim 28, wherein the digital control circuit is configured to modulate the frequency of the gate drive signal based on a function of the phase measurement, the function of the phase measurement comprising one or more functions from a list including:
a saw tooth function;
a polynomial function;
a linear function;
a hyperbolic function;
a sinusoidal function; and
a digital function that modulates the frequency of the gate drive signal according to discrete frequency steps.

35. The SMPS of claim 28, wherein modulating the frequency of the gate drive signal comprises adjusting the gate drive signal according to a first mode of operation and a second mode of operation, wherein
the first mode of operation comprises modulating the frequency of the gate drive signal according to a function of the phase measurement; and
the second mode of operation comprises adjusting the gate drive signal according to a quasi-resonant mode of operation.
